(19) United States
(12) Patent Application Publication
(10) Pub. No.: US 2008/0150101 A1
(43) Pub. Date: Jun. 26, 2008

(54) Microelectronic packages having improved input/output connections and methods therefor

(75) Inventors: Charles White, Los Altos, CA (US); Belgacem Haba, Saratoga, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/643,041

(22) Filed: Dec. 20, 2006

(51) Int. Cl. H01L 23/495

(52) U.S. Cl. 257/668; 257/666; 427/99.2; 257/E23.031

(57) ABSTRACT

A microelectronic assembly includes a microelectronic package, such as a semiconductor package, having a plurality of conductive posts projecting from an exposed surface thereof. The assembly includes a microelectronic element, such as a dielectric film having a first surface and an array of contact pads accessible at the first surface. The array of contact pads include a central region and a peripheral region, wherein at least some of the contact pads in the peripheral region are larger than at least some of the contact pads in the central region. The larger contact pads cover a larger area of the microelectronic element than the smaller contact pads in the central region.

### FIELD OF THE INVENTION

The present invention relates to microelectronic assemblies and in particular to microelectronic assemblies having improved input/output connections.

### BACKGROUND OF THE INVENTION

Microelectronic devices such as semiconductor chips typically require many input and output connections to other electronic components. The input and output contacts of a semiconductor chip or other comparable device are generally disposed in grid-like patterns that substantially cover a surface of the device (commonly referred to as an “area array”) or in elongated rows that extend parallel to and adjacent each edge of the device, or in the center of the front surface of the device. Typically, devices such as chips must be physically mounted on a substrate such as a printed circuit board, and the contacts of the device must be electrically connected to electrically conductive features of the circuit board.

Semiconductor chips are commonly provided in packages that facilitate handling of the chip during manufacture and during mounting of the chip on an external substrate such as a circuit board or other circuit panel. Most commonly, such packages include a dielectric element, commonly referred to as an “interposer” or a “chip carrier” with terminals formed as plated or etched metallic structures on the dielectric element.

The dielectric elements are typically provided as tapes in the form of sheets or rolls of sheets. For example, single and double sided sheets of copper-on-polyimide are commonly used for fine-line and high-density electronic interconnection applications. Polyimide based films offer good thermal and chemical stability and a low dielectric constant, while copper having high tensile strength, ductility, and flexure has been advantageously used in both flexible circuit and chip scale packaging applications. However, such tapes are relatively expensive, particularly as compared to lead frames and laminate substrates.

The terminals on the dielectric element are typically connected to the contacts of the chip itself by features such as thin traces extending along the chip carrier or by fine leads or wires extending between the contacts of the chip and the terminals or traces. In a surface mounting operation, the package is placed onto a circuit board so that each terminal on the package is aligned with a corresponding contact pad on the circuit board. Solder or other bonding material is provided between the terminals and the contact pads. The package can be permanently bonded in place by heating the assembly so as to melt or “reflow” the solder or otherwise activate the bonding material.

Many packages include solder masses in the form of solder balls, typically about 0.1 mm and about 0.8 mm (5 and 30 mils) in diameter, attached to the terminals of the package. A package having an array of solder balls projecting from its bottom surface is commonly referred to as a ball grid array or “BGA” package. Other packages, referred to as land grid array or “LGA” packages are secured to the substrate by thin layers or lands formed from solder. Packages of this type can be quite compact. Certain packages, commonly referred to as “chip scale packages,” occupy an area of the circuit board equal to, or only slightly larger than, the area of the integrated circuit device incorporated in the package. This is advantageous in that it reduces the overall size of the assembly and permits the use of short interconnections between various devices on the substrate, which in turn limits signal propagation time between devices and thus facilitates operation of the assembly at high speeds.

Assemblies including packages can suffer from stresses imposed by differential thermal expansion and contraction of the device and the substrate. During operation, as well as during manufacture, a semiconductor chip tends to expand and contract by an amount different from the amount of expansion and contraction of a circuit board. Where the terminals of the package are fixed relative to the chip or other device, such as by using solder, these effects tend to cause the terminals to move relative to the contact pads on the circuit board. This can impose stresses in the solder that connects the terminals to the contact pads on the circuit board. As disclosed in certain preferred embodiments of U.S. Pat. Nos. 5,679,977; 5,148,266; 5,148,265; 5,455,390; and 5,518,964, the disclosures of which are incorporated by reference herein, semiconductor chip packages can have terminals that are movable with respect to the chip or other device incorporated in the package. Such movement can compensate to an appreciable degree for differential expansion and contraction.

Depending on the configuration and other requirements of the microelectronic package, different materials may be used for the chip carrier. For example, in a flip-chip configuration, the front or contact-bearing surface of the microelectronic device faces towards a substrate. Each contact on the device is joined by a solder bond to a corresponding contact pad on the substrate, by positioning solder balls on the substrate or device, juxtaposing the device with the substrate, and momentarily reflowing the solder. Flip-chip configurations, however, may encounter problems in thermal expansion mismatch. When the coefficient of thermal expansion (CTE) for the device differs significantly from the CTE for the substrate, the solder connections will undergo fatigue when the package is thermally cycled. This is particularly problematic for flip-chip packages with fine pitch, small bumps, and/or large device footprints. Thus, to enhance reliability, the substrate is typically selected so that the CTE of the substrate closely matches the CTE of the device.

Testing of packaged devices poses another formidable problem. In some manufacturing processes, it is necessary to make temporary connections between the terminals of the packaged device and a test fixture, and operate the device through these connections to assure that the device is fully functional. Ordinarily, these temporary connections must be made without bonding the terminals of the package to the test fixture. It is important to assure that all of the terminals are reliably connected to the conductive elements of the test fixture. However, it is difficult to make connections by pressing the package against a simple test fixture such as an ordinary circuit board having planar contact pads. If the terminals of the package are not coplanar, or if the conductive elements of the test fixture are not coplanar, some of the terminals will not contact their respective contact pads on the test fixture. For example, in a BGA package, differences in the diameter of the solder balls attached to the terminals, and non-planarity of the chip carrier, may cause some of the solder balls to lie at different heights.

Commonly assigned U.S. Pat. No. 6,177,636, the disclosure of which is hereby incorporated by reference herein, discloses a method and apparatus for providing interconnections between a microelectronic device and a supporting substrate. In one preferred embodiment of the '636 patent, a method of fabricating an interconnection component for a microelectronic device includes providing a flexible chip carrier having first and second surfaces and coupling a conductive sheet to the first surface of the chip carrier. The conductive sheet is then selectively etched to produce a plurality of substantially rigid posts. A compliant layer is provided on the second surface of the support structure and a microelectronic device such as a semiconductor chip is engaged with the compliant layer so that the compliant layer lies between the microelectronic device and the chip carrier, and leaving the posts projecting from the exposed surface of the chip carrier. The posts are electrically connected to the microelectronic device. The posts form projecting package terminals that can be engaged in a socket or solder-bonded to features of a substrate as, for example, a circuit panel. Because the posts are movable with respect to the microelectronic device, such a package substantially accommodates thermal coefficient of expansion mismatches between the device and a supporting substrate when the device is in use. Moreover, the tips of the posts can be coplanar or nearly coplanar.

Microelectronic packages also include wafer level packages, which provide an enclosure for a semiconductor component that is fabricated while the die are still in a wafer form. The wafer is subject to a number of additional process steps to form the package structure and the wafer is then diced to free the individual die, with no additional fabrication steps being necessary. Wafer level processing provides an advantage in that the cost of the packaging processes are divided among the various die on the wafer, resulting in a very low price differential between the die and the component.

In spite of the above-described advances in the art, still further improvements in microelectronic packages and methods of making microelectronic packages would be desirable. There also remains a need for microelectronic packages and assemblies having improved input/output connections.

### SUMMARY OF THE INVENTION

The present invention discloses various embodiments for improving the reliability of electrically interconnections found in microelectronic assemblies. In particular, the present invention provides improved input/output connections for microelectronic assemblies by providing stronger electrical interconnections at high stress joints. In one aspect of the invention, larger contact pads are provided at the input/output locations where higher stresses are likely to occur. Such high stress points are typically present at the periphery or the corners of a microelectronic device. In one embodiment, the present invention provides a microelectronic device having larger contact pads at high stress locations and smaller contact pads at lower stress locations. Using smaller contact pads at the lower stress locations reduces the overall size of the microelectronic device. The invention may also provide larger conductive pins that are aligned with the larger contact pads for forming a more reliable electrical interconnection with the larger contact pads. In addition, more conductive bonding material such as solder may be used at the larger contact pads for enhancing structural support while avoiding solder bridging between adjacent contact pads.

In one aspect of the present invention, a microelectronic assembly includes a microelectronic package, such as a semiconductor chip package or a semiconductor wafer package, having a plurality of posts projecting from an exposed surface thereof. The microelectronic assembly includes a microelectronic element having a first surface and an array of contact pads accessible at the first surface. At least one of the contact pads is larger than another one of the contact pads. In one embodiment, the array of contact pads includes a central region and a peripheral region, whereby at least one of the contact pads in the peripheral region is larger than at least one of the contact pads in the central region. The at least one larger contact pad desirably covers a larger area of the first surface of the microelectronic element than the at least one smaller contact pad. In an embodiment, the array of contact pads has a square, box or rectangular shape and one or more of the corner contact pads in the square, box or rectangular shaped array are larger than the contact pads located inside the corner contact pads.

In one embodiment, some of the posts are conductive posts for electrically interconnecting the microelectronic package and the microelectronic element. The conductive posts are preferably in contact with one or more of the contact pads for forming an electrical interconnection. The electrical interconnection may be permanently formed using a conductive bonding material such as solder. The masses of electrically conductive bonding material may form fillets that extend around the tips of the conductive posts. The electrically conductive bonding material may include solder. In one aspect of the present invention, the masses of the electrically conductive bonding material that cover the larger contact pads have a greater volume than the masses of the electrically conductive bonding material covering the smaller contact pads. The larger volume of conductive bonding material on the larger contact pads enables the conductive bonding material to extend further up the outer surface of the conductive post, which enhances the bond between the larger contact pads and the conductive posts aligned with the larger contact pads.

In one embodiment, the conductive posts have tips remote from the microelectronic package. During assembly, the tips preferably confront the contact pads for electrically interconnecting the conductive posts with the contact pads. In another embodiment, at least some of the posts may be non-conductive for mechanically interconnecting the microelectronic package and the microelectronic element.

In one embodiment, at least some of the conductive post tips have larger cross-sectional diameters than other ones of the conductive post tips. The conductive post tips having larger cross-sectional diameters are desirably aligned with the larger contact pads. In another aspect of the invention, at least some of the conductive post tips have cross sections that are non-circular. The conductive post tips having non-circular cross sections are preferably aligned with the larger contact pads.

In one embodiment of the present invention, the microelectronic element includes a circuitized substrate such as a printed circuit board or a circuitized dielectric substrate. Conductive traces may be provided on the circuitized substrate. The dielectric substrate may be a chip carrier that may be connected with another substrate or another microelectronic package.

In one aspect of the invention, a layer of a compliant material is preferably disposed between the microelectronic package and the microelectronic element. In another aspect of the invention, the microelectronic element of the microelectronic assembly may include a second microelectronic package that is stackable with the first microelectronic package. The microelectronic assembly may include a plurality of stacked microelectronic packages, each having conductive posts that are electrically interconnected with contact pads provided on an adjacent package in the stack.

In another aspect of the present invention, a microelectronic assembly includes a first microelectronic element having a plurality of posts, such as conductive posts, projecting from an exposed surface thereof, the posts having tips remote from the exposed surface, and a second microelectronic element having a first surface and an array of contact pads accessible at the first surface, the array of contact pads including a peripheral region and a central region. At least some of the contact pads in the peripheral region are desirably larger than at least some of the contact pads in the central region. The larger contact pads in the peripheral region desirably cover a larger area than the smaller contact pads in the central region.

In one embodiment, the first microelectronic element includes a semiconductor package. The second microelectronic element may be a second microelectronic package, a circuitized substrate, a printed circuit board or a dielectric sheet. The second microelectronic element desirably includes posts, such as conductive posts, projecting from an exposed surface thereof.

The conductive posts on the microelectronic elements have tips remote from the exposed surface. At least some of the conductive post tips desirably have larger diameters than other ones of the conductive post tips. The larger diameter conductive posts are desirably aligned with the larger contact pads. At least some of the conductive post tips may have cross sections that are non-circular. Larger volumes of conductive bonding material may be provided atop the larger contact pads for improving the bond between the posts and the larger contact pads. The larger volume of the conductive bonding material on the larger contact pads will enable the bonding material to extend further over the outer surface of the aligned conductive post to enhance the bond between the posts and the opposing pads.

In another aspect of the present invention, a microelectronic assembly includes a microelectronic package having a plurality of posts projecting from an exposed surface thereof, and a microelectronic substrate having a first surface with a plurality of contact pads accessible at the first surface. The contact pads desirably form an array of contact pads having a central region and a peripheral region, whereby at least some of the contact pads in the peripheral region cover a larger area of the microelectronic substrate than at least some of the contact pads in the central region.

The posts are preferably conductive posts for electrically interconnecting the microelectronic package and the microelectronic substrate. The conductive posts desirably have tips remote from the exposed surface, and the conductive post tips in contact with the larger contact pads in the peripheral region have a larger diameter than the conductive post tips in contact with the smaller contact pads. A mass of a conductive bonding material may interconnect each of the conductive posts with one of the contact pads. The masses of the conductive bonding material interconnecting the conductive posts with the larger contact pads desirably have a greater volume than the masses of the conductive bonding material interconnecting the conductive posts with the smaller contact pads.

In one embodiment, the array of contact pads comprises rows of contact pads and at least some of the contact pads in outer ones of the rows cover larger surface areas than at least some of the contact pads in inner ones of the rows. The array of contact pads may also include corner contact pads, whereby the corner contact pads are larger in area than the contact pads in the central region.

In another aspect of the invention, a microelectronic assembly includes a microelectronic package having a plurality of conductive posts projecting from an exposed surface thereof, the conductive posts having tips remote from the exposed surface, whereby at least one of the conductive post tips has a larger diameter than other ones of the conductive post tips. The assembly desirably includes a circuitized substrate having an array of contact pads accessible at a first surface thereof, the array of contact pads including a central region and a peripheral region, whereby the array of contact pads includes at least one large area contact pad in the peripheral region and at least one small area contact pad, whereby the at least one of the conductive post tips having a larger diameter is electrically interconnected with the at least one large area contact pad.

The assembly may also include masses of conductive bonding material provided atop the contact pads for electrically interconnecting the conductive posts with the contact pads. The volume of the masses of conductive bonding material atop the large area contact pads is preferably greater than the volume of the masses of conductive bonding material atop the smaller contact pads for enhancing the bonds between the posts and pads at high stress locations.

In another aspect of the present invention, a method of making a microelectronic assembly includes providing a microelectronic element having a first surface and an array of contact pads accessible at the first surface, the array of contact pads including a central region having one or more smaller contact pads and a peripheral region having one or more larger contact pads. The method desirably includes providing a microelectronic package having a plurality of conductive posts projecting from an exposed surface thereof, the conductive posts having tips remote from the exposed surface. The method preferably includes depositing a mass of a conductive bonding material atop each of the contact pads. The tips of the conductive posts are desirably abutted against the masses of a conductive bonding material for electrically interconnecting the microelectronic element and the microelectronic package. More conductive bonding material may be provided atop the larger contact pads for enhancing the bond strength between the larger contact pads and the conductive posts aligned with the larger contact pads. The posts aligned with the larger pads may have greater tip diameter or non-circular tips.

### BRIEF DESCRIPTION OF THE DRAWINGS

FIG. 1 is a diagrammatic sectional view of a microelectronic package according to one embodiment of the invention.

FIG. 2 is a fragmentary plan view of the microelectronic package shown in FIG. 1.

FIG. 3 is a diagrammatic elevational view depicting the microelectronic package of FIGS. 1-2 in conjunction with a substrate during one step of a method according to one embodiment of the invention.

FIG. 4 is a view similar to FIG. 3 but depicting a later stage of the method.

FIGS. 5A-5G show a method of making a microelectronic element according to one embodiment of the present invention.

FIGS. 6A-6B show a microelectronic package according to another embodiment of the present invention.

FIG. 7A shows a stackable microelectronic package according to one embodiment of the present invention.

FIG. 7B shows a stacked microelectronic assembly including the microelectronic package of FIG. 7A.

FIG. 8 shows a plan view of a microelectronic element.

FIG. 9 shows a plan view of a microelectronic element according to an embodiment of the present invention.

FIG. 10 shows a plan view of another microelectronic element.

FIG. 11 shows a plan view of a microelectronic element according to another embodiment of the present invention.

FIG. 12 shows a plan view of a microelectronic element according to an embodiment of the present invention.

FIG. 13 shows a plan view of a microelectronic element according to another embodiment of the present invention.

FIG. 14 shows a fragmentary cross-sectional view of a microelectronic package electrically interconnected with the microelectronic element of FIG. 13.

FIG. 15 shows a plan view of a microelectronic element according to another embodiment of the present invention.

FIG. 16 shows a plan view of a microelectronic element according to another embodiment of the present invention.

FIG. 17 shows a plan view of a microelectronic element according to another embodiment of the present invention.

FIG. 18 shows a plan view of a microelectronic element according to another embodiment of the present invention.

FIG. 19 shows conductive posts according to additional embodiments of the invention.

### DETAILED DESCRIPTION

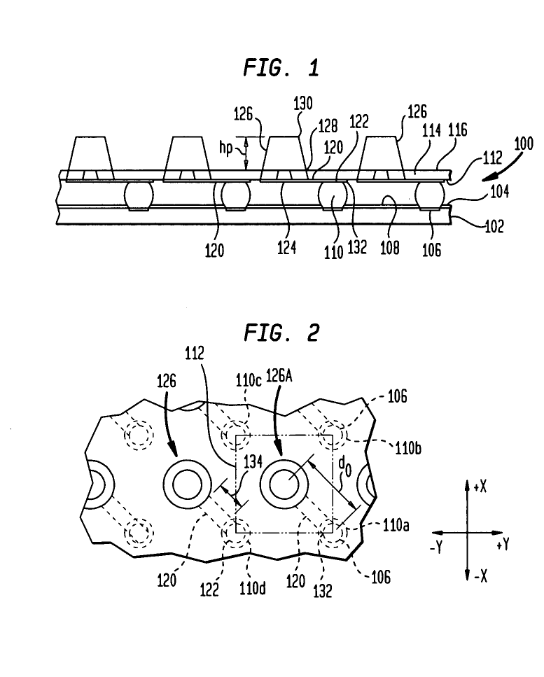

Referring to FIGS. 1 and 2, in accordance with one preferred embodiment of the present invention, a microelectronic package 100 includes a microelectronic element, such as a semiconductor chip 102 or a semiconductor wafer, having a front or contact bearing face 104 and electrical contacts 106 accessible at the face 104. A passivation layer 108 may be formed over the contact bearing face 104. The passivation layer 108 preferably has openings aligned with the contacts 106 so that the contacts are accessible through the passivation layer.

The microelectronic package 100 also includes conductive support elements 110 such as solder balls in substantial alignment and electrically interconnected with contacts 106. As best seen in FIG. 2, the contacts 106 and the support elements 110 are disposed in an array which in this case is a rectilinear grid, having equally spaced columns extending in a first horizontal direction x and equally spaced rows extending in a second horizontal direction y orthogonal to the first horizontal direction. Each contact 106 and support element 110 is disposed at an intersection of a row and a column, so that each set of four support elements 110 at adjacent intersections, such as support elements 110a, 110b, 110c and 110d, defines a generally rectangular, and preferably square, zone 112. The directions referred to in this disclosure are directions in the frame of reference of the components themselves, rather than in the normal gravitational frame of reference. Horizontal directions are directions parallel to the plane of the front surface 104 of the chip, whereas vertical directions are perpendicular to that plane.

The microelectronic package also includes a flexible dielectric substrate 114, such as a polyimide or other polymeric sheet, including a top surface 116 and a bottom surface 118 remote therefrom. Although the thickness of the dielectric substrate will vary with the application, the dielectric substrate most typically is about 10 μm-100 μm thick. The flexible sheet 114 has conductive traces 120 thereon. In the particular embodiment illustrated in FIG. 1, the conductive traces are disposed on the bottom surface 118 of the flexible sheet 114. In other preferred embodiments, however, the conductive traces 120 may extend on the top surface 116 of the flexible sheet 114, on both the top and bottom faces or within the interior of the flexible substrate 114. Thus, as used in this disclosure, a statement that a first feature is disposed “on” a second feature should not be understood as requiring that the first feature lie on a surface of the second feature. Conductive traces 96 may be formed from any electrically conductive material, but most typically are formed from copper, copper alloys, gold or combinations of these materials. The thickness of the traces will also vary with the application, but typically is about 5 μm-25 μm. The conductive traces 120 are arranged so that each trace has a support end 122 and a post end 124 remote from the support end.

Electrically conductive posts or pillars 126 project from the top surface 116 of flexible substrate 114. Each post 126 is connected to the post end 124 of one of the traces 120. In the particular embodiment of FIGS. 1 and 2, the posts 126 extend upwardly through the dielectric sheet 114, from the post ends of the traces. The dimensions of the posts can vary over a significant range, but most typically the height hp of each post above the top surface 116 of the flexible sheet is about 50-300 μm. Each post has a base 128 adjacent the flexible sheet 114 and a tip 130 remote from the flexible sheet. In the particular embodiment illustrated, the posts are generally frustoconical, so that the base 128 and tip 130 of each post are substantially circular. The bases of the posts typically are about 100-600 μm in diameter, whereas the tips typically are about 40-200 μm in diameter. The posts may be formed from any electrically conductive material, but desirably are formed from metallic materials such as copper, copper alloys, gold and combinations thereof. The posts may be etched from a layer of a conductive material such as metal. In one embodiment, the posts may be formed principally from copper with a layer of gold at the surfaces of the posts.

The dielectric sheet 114, traces 120 and posts 126 can be fabricated by a process such as that disclosed in co-pending, commonly assigned U.S. Provisional Patent Application Ser. No. 60/508,970, the disclosure of which is incorporated by reference herein. As disclosed in greater detail in the '970 application, a metallic plate is etched or otherwise treated to form numerous metallic posts projecting from the plate. A dielectric layer is applied to this plate so that the posts project through the dielectric layer. An inner or side of the dielectric layer faces toward the metallic plate, whereas the outer side of the dielectric layer faces towards the tips of the posts. The dielectric layer may be fabricated by coating a dielectric such as polyimide onto the plate around the posts or, more typically, by forcibly engaging the posts with the dielectric sheet so that the posts penetrate through the sheet. Once the sheet is in place, the metallic plate is etched to form individual traces on the inner side of the dielectric layer. Alternatively, conventional processes such as plating may form the traces or etching, whereas the posts may be formed using the methods disclosed in commonly assigned U.S. Pat. No. 6,177,636, the disclosure of which is hereby incorporated by reference herein. In yet another alternative, the posts may be fabricated as individual elements and assembled to the flexible sheet in any suitable manner, which connects the posts to the traces.

Referring to FIG. 2, the support ends 122 of the leads are disposed in a regular grid pattern corresponding to the grid pattern of the support elements, whereas the posts 126 are disposed in a similar grid pattern. However, the grid pattern of the posts is offset in the first and second horizontal directions x and y from the grid pattern of the support ends 122 and support elements 110, so that each post 126 is offset in the −y and +x directions from the support end 122 of the trace 120 connected to that post.

The support end 122 of each trace 120 overlies a support element 110 and is bonded to such support element, so that each post 126 is connected to one support element. In the embodiment illustrated, where the support elements are solder balls, the bonds can be made by providing the support elements on the contacts 106 of the chip and positioning the substrate or flexible sheet 114, with the posts and traces already formed thereon, over the support elements and reflowing the solder balls by heating the assembly. In a variant of this process, the solder balls can be provided on the support ends 122 of the traces. The process steps used to connect the support ends of the traces can be essentially the same used in flip-chip solder bonding of a chip to a circuit panel.

As mentioned above, the posts 126 are offset from the support elements 110 in the x and y horizontal directions. Unless otherwise specified herein, the offset distance dₒ (FIG. 2) between a post and a support element can be taken as the distance between the center of area of the base 128 (FIG. 1) of the post and the center of area of the upper end 132 (FIG. 1) of the support element 110. In the embodiment shown, where both the base of the post and the upper end of the support element have circular cross-sections, the centers of area lie at the geometric centers of these elements. Most preferably, the offset distance dₒ is large enough that there is a gap 134 (FIG. 2) between adjacent edges of the base of the post and the top end of the support element. Stated another way, there is a portion of the dielectric sheet 114 in gap 134, which is not in contact with either the top end 132 of the support element or the base 128 of the post.

Each post lies near the center of one zone 112 defined by four adjacent support elements 110, so that these support elements are disposed around the post. For example, support elements 110a-110d are disposed around post 126A. Each post is electrically connected by a trace and by one of these adjacent support elements to the microelectronic device 102. The offset distances from a particular post to all of the support elements adjacent to that post may be equal or unequal to one another.

In the completed unit, the upper surface 116 of the substrate or flexible sheet 114 forms an exposed surface of the package, whereas posts 126 project from this exposed surface and provide terminals for connection to external elements.

The conductive support elements 110 create electrically conductive paths between the microelectronic element 102 and the flexible substrate 114 and traces 120. The conductive support elements space the flexible substrate 114 from the contact bearing face 104 of microelectronic element 102. As further discussed below, this arrangement facilitates movement of the posts 126.

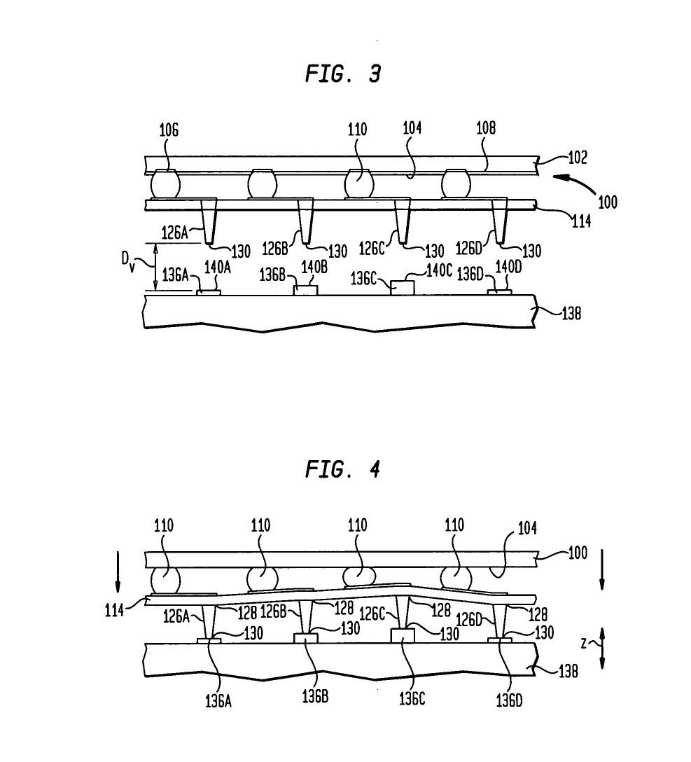

Referring to FIG. 3, the microelectronic package 100 discussed above with reference to FIGS. 1 and 2 is tested by juxtaposing the conductive posts 126 with contact pads 136 on a second microelectronic element 138 such as a circuitized test board 138. The conductive posts 126A-126D are placed in substantial alignment with top surfaces of the respective contact pads 136A-136D. As is evident in the drawing figure, the top surfaces 140A-140D of the respective contact pads 136A-136D are disposed at different heights and do not lie in the same plane. Such non-planarity can arise from causes such as warpage of the circuit board 138 itself and unequal thicknesses of contact pads 136. Also, although not shown in FIG. 3, the tips 130 of the posts may not be precisely coplanar with one another, due to factors such as unequal heights of support elements 110; non-planarity of the front surface 104 of the microelectronic device; warpage of the dielectric substrate 114; and unequal heights of the posts themselves. Also, the package 100 may be tilted slightly with respect to the circuit board. For these and other reasons, the vertical distances Dv between the tips 130 of the posts 126 and the contact pads 140 may be unequal.

Referring to FIG. 4, in order to test the microelectronic package 100, the package is moved toward the test board 138, by moving the test board, the package or both. The tips 130 of the conductive posts 126A-126D engage the contact pads 136 and make electrical contact with the contact pads. The tips of the posts are able to move so as to compensate for the initial differences in vertical spacing Dv (FIG. 3), so that all of the tips can be brought into contact with all of the contact pads simultaneously using only a moderate vertical force applied to urge the package and test board 138 together. In this process, at least some of the post tips are displaced in the vertical or z direction relative to other post tips.

A significant portion of this relative displacement arises from movement of the bases 128 of the posts relative to one another and relative to microelectronic element 100. Because the posts are attached to flexible substrate 114 and are offset from the support elements 110, and because the support elements space the flexible substrate 114 from the front surface 104 of the microelectronic element, the flexible substrate can deform. Further, different portions of the substrate associated with different posts can deform independently of one another. After testing or burn-in, the microelectronic package may be permanently attached to the substrate 138 using conductive bonding material such as solder for bonding the post tips 130 to the contact pads 136. Although the substrate 138 is described as a test board, it may also be a circuitized substrate such as a printed circuit board.

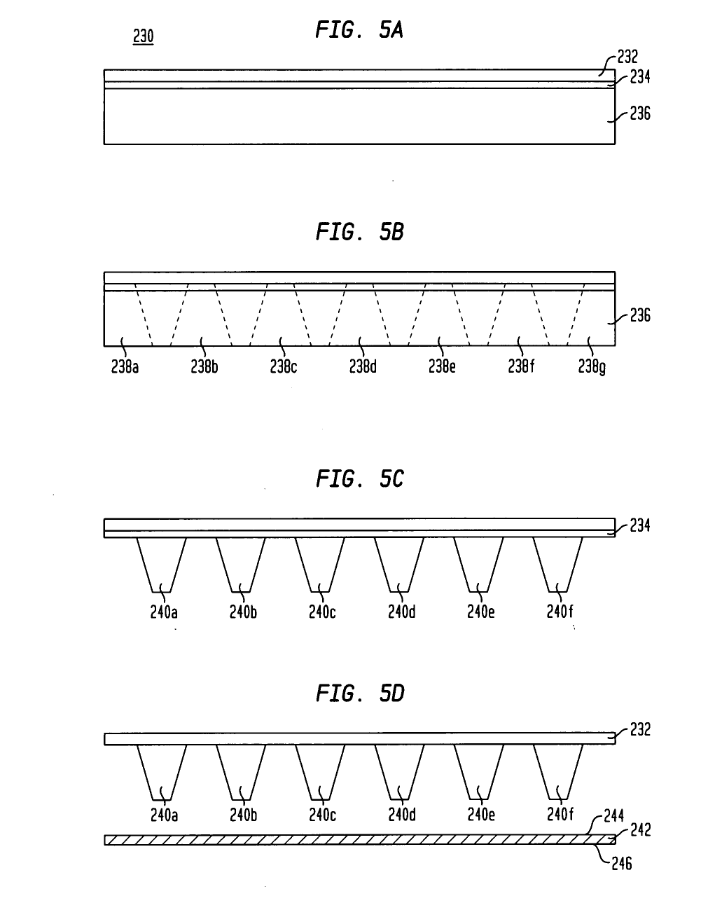

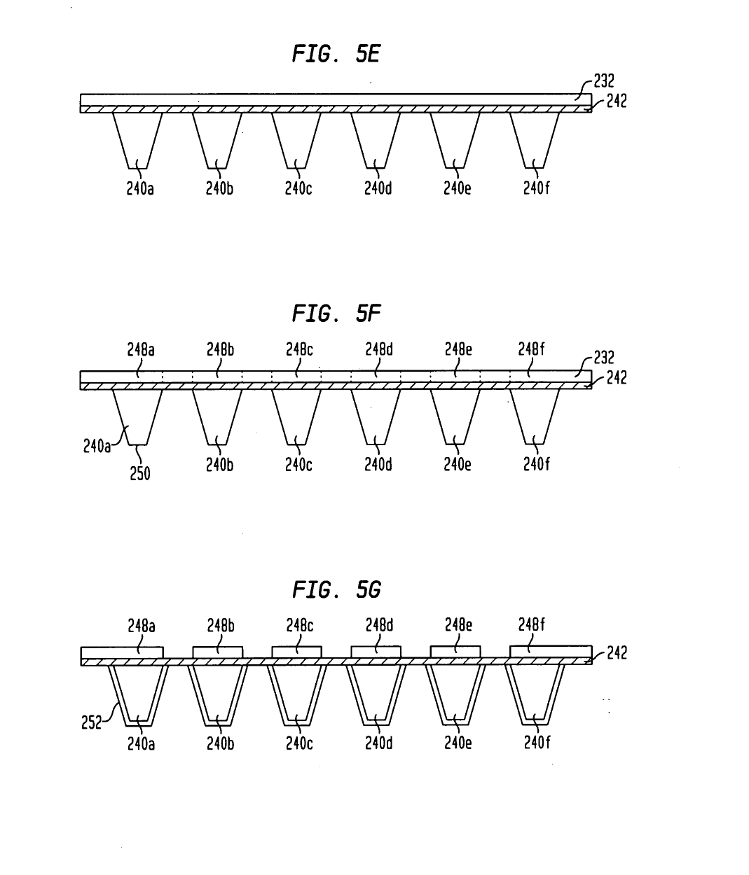

Referring to FIG. 5A, in one preferred embodiment of the present invention, a microelectronic assembly may be fabricated by a process such as that disclosed in certain preferred embodiments of co-pending, commonly assigned U.S. Provisional Application No. 60/508,970 and U.S. patent application Ser. No. 11/140,312, filed May 27, 2005 [TESSERA 3.0-415], the disclosures of which are hereby incorporated by reference herein. As shown in FIG. 5A, a metallic plate 230 includes a top layer 232 made of a conductive material, an intermediate etch stop layer 234 and a bottom layer 236 made of a conductive material. The top and bottom layers 232, 236 may include electrically conductive materials such as copper. The intermediate etch stop layer 234 may include materials such as nickel. Referring to FIGS. 5B and 5C, the bottom layer 236 of metallic plate 230 is stamped or etched to remove portions 238a-238g of bottom layer 236 so as to form conductive terminals or posts 240a-240f. Referring to FIGS. 5C and 5D, after the posts 240a-240f have been formed, the etch stop layer 234 (FIG. 5C) is removed by a process that leaves the top layer 232 and the posts 240a-240f in place. One preferred method for removing the etch stop layer includes a chemical etching process.

The dimensions of the conductive posts may vary over a significant range, but most typically the height of each post above the surface of the dielectric substrate is about 50-300 μm. Each post has a base adjacent the dielectric substrate and a tip remote from the dielectric substrate. In certain preferred embodiments, the posts are generally frustoconical, so that the base and tip of each post are substantially circular. The bases of the posts typically are about 100-600 μm in diameter, whereas the tips typically are about 40-200 μm in diameter. The posts may be formed from any electrically conductive material, but desirably are formed from metallic materials such as copper, copper alloys, gold and combinations thereof. For example, the posts may be formed principally from copper with a layer of gold at the surfaces of the posts.

Referring to FIGS. 5D and 5E, a flexible dielectric sheet 242 such as a polyimide film is assembled with the top layer 232 and the posts 240a-240f so that the posts 240a-240f project through the dielectric layer 242. As shown in FIG. 5D, a first face 244 of the dielectric layer 242 faces toward the top layer 232 and a second face 246 faces away from the top layer 232. The dielectric layer 242 may be fabricated by coating a dielectric layer such as a polyimide onto the top layer 232 and around the terminals 240a-240f. In other preferred embodiments, the dielectric layer 242 may be assembled with the top layer 232 and the conductive posts 240a-240f by forcibly engaging the terminals with the dielectric sheet so that the terminals penetrate through the sheet. Although the thickness of the dielectric layer 242 may vary according to the application, the dielectric layer is preferably about 15-100 μm thick. Referring to FIG. 5F, once the dielectric layer 242 is in place, the top layer 232 is etched to form individual conductive traces 248a-248f on the first face 244 of the dielectric layer 242.

In certain preferred embodiments, the conductive traces are disposed on a bottom surface of the dielectric layer. However, in other embodiments, the conductive traces may extend on the top surface of the dielectric layer; on both the top and bottom faces or within the interior of the dielectric layer. Thus, as used in this disclosure, a statement that a first feature is disposed “on” a second feature should not be understood as requiring that the first feature lie on a surface of the second feature. The conductive traces may be formed from any electrically conductive material, but most typically are formed from copper, copper alloys, gold or combinations of these materials. The thickness of the traces will also vary with the application, but typically is about 5 μm-25 μm.

In the embodiment illustrated in FIGS. 5A-5F, the flexible dielectric layer 242 is assembled with top layer 232 before the top layer is treated. However, in other embodiments, the flexible dielectric layer 242 may be attached to the top layer 232 after the conductive traces 248a-248f (FIG. 5F) have been formed, or at a later process step. In other preferred embodiments, conventional processes such as plating may form the traces. An etching process may also be used, whereby the conductive posts 240a-240f may be formed using the methods disclosed in commonly assigned U.S. Pat. No. 6,177,636, the disclosure of which is hereby incorporated by reference herein. In yet other preferred embodiments, the conductive posts 240a-240f may be fabricated as individual elements and assembled to the flexible dielectric layer in any suitable manner that connects the conductive posts 240a-240f to the conductive traces 248a-248f. As used herein, the terminology “conductive terminal” may also mean a conductive bump, or a conductive post having a height significantly greater than its width. The tips of the conductive posts are preferably flat and the flat tips are preferably co-planar.

Referring to FIGS. 5F and 5G, each conductive post 240a-240f has an exposed contact surface 250. Referring to FIG. 5G, a highly conductive metal layer 252 such as gold may be formed over an outer surface of the conductive posts 240a-240f. The assembly shown in FIG. 5G may be referred to as a connection component 254.

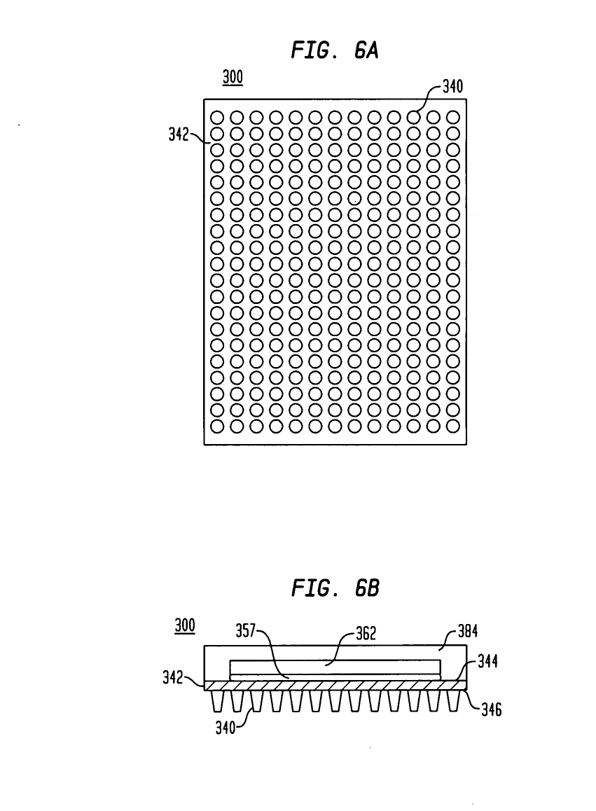

FIGS. 6A and 6B show a microelectronic package 300, in accordance with one preferred embodiment of the present invention. The microelectronic package 300 includes a dielectric substrate 342 having a first surface 344 and a second surface 346 remote therefrom. The package 300 includes a plurality of conductive posts 340 projecting from the second surface 346 of the dielectric substrate 342. The package 300 includes a microelectronic element 362 such as a semiconductor chip that is electrically interconnected with the conductive posts 340. The package includes an adhesive 357 for attaching the microelectronic element 362 to the dielectric substrate 342. Package 300 also includes an overmold 384 that encapsulates the microelectronic element 362 and covers the first surface 344 of the dielectric layer 342. The package 300 may be electrically interconnected with a substrate by aligning the post tips with contact pads on the substrate.

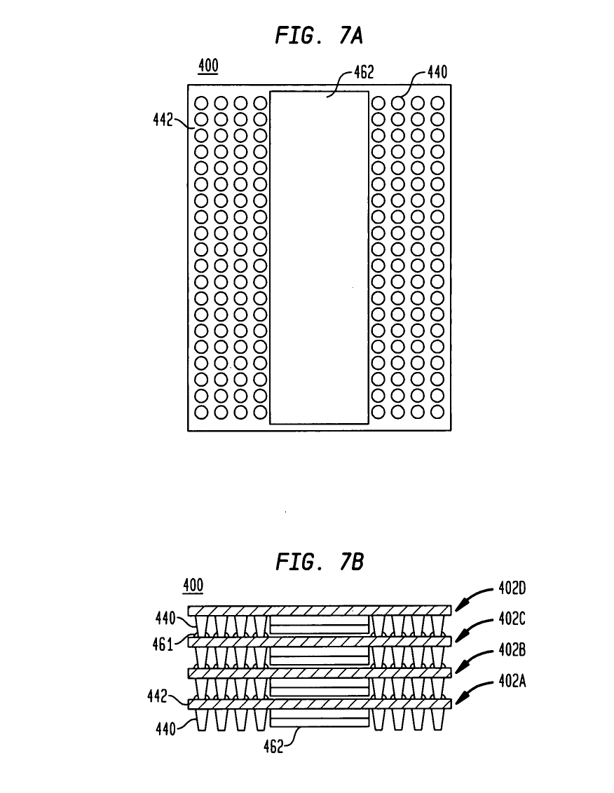

FIGS. 7A and 7B show a microelectronic assembly 400 including a plurality of microelectronic packages 402a-402d that are stacked one atop another. Each microelectronic package 402 includes a dielectric layer 442 having conductive posts 440 projecting therefrom. Each microelectronic package 490 also includes one or more microelectronic elements 462 attached to the dielectric layer 442 and electrically interconnected with one or more of the conductive posts 440. The dielectric layer 442 may be flexible. In other preferred embodiments, the dielectric layer 442 may be substantially rigid. As shown in FIG. 7B, the individual microelectronic packages 490 are stacked one atop the other. In one particular embodiment, the conductive packages are stacked one atop the other so that the conductive posts 440 of one package are in general alignment with the contact pads of an adjacent package. The conductive posts 440 of fourth microelectronic package 402d are electrically interconnected with third microelectronic package 402c using conductive bonding material 461 such as solder. The conductive material 461 bonds and electrically interconnects the conductive posts of an upper package to the substrate 442 of a lower package. As a result, the conductive posts 440 are bonded to the underlying contact pads. In one embodiment, the conductive posts of second, third and fourth microelectronic packages 402b-402d may be rigidly locked, while the conductive posts of the first microelectronic package 402a are free to move relative to one another.

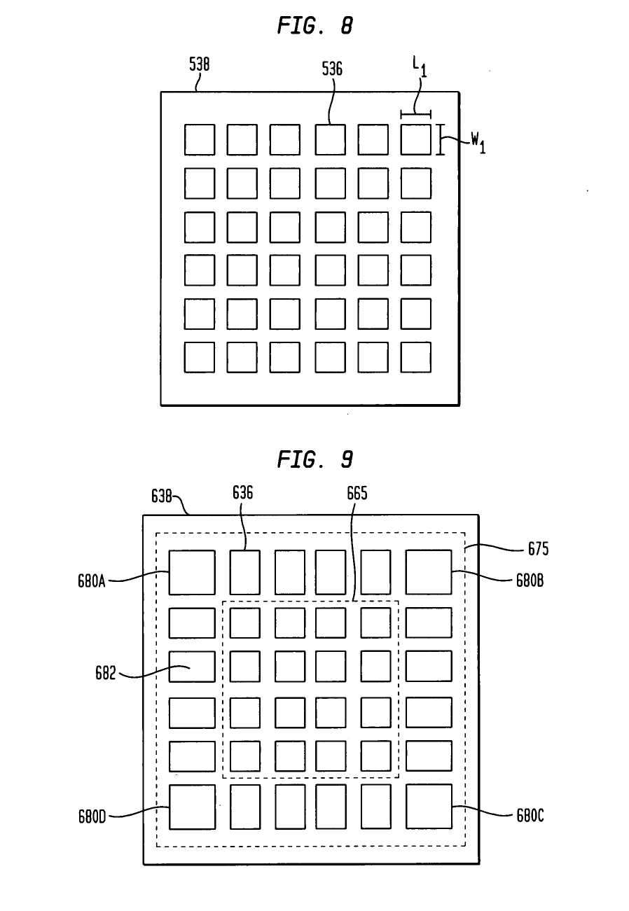

Referring to FIG. 8, in one embodiment of the present invention, a microelectronic assembly includes a microelectronic element 538 having an array of contact pads 536 accessible at a first surface thereof. Each of the contact pads 536 has a length L₁ and width W₁ that define an area of the contact pad. All of the contacts pads 536 cover the same area on the microelectronic element.

Referring to FIG. 9, in one embodiment of the present invention, a microelectronic element 638 has a plurality of contact pads 636 accessible at a first surface thereof. The array of contacts pads 636 includes a central region 665 and a peripheral region 675 that surrounds the central region 665. The contact pads located in the central region 665 are smaller than corner contact pads 680A-680D located in the peripheral region 675. The microelectonic element 638 also includes outer rows of contact pads 682 that lie in the peripheral region 675 and that extend between the corner contact pads 680A-680D. The contact pads 682 in the outer rows cover an area that is larger than the contact pads in the central region 665, however, the contact pads 682 in the outer rows are smaller than the corner contact pads 668A-680D. In one preferred embodiment, the microelectronic element 638 is a circuitized substrate such as a printed circuit board or a circuitized dielectric film. In another embodiment, the microelectronic element 638 may be part of a microelectronic assembly such as a microelectronic package having a semiconductor chip or a semiconductor wafer. The microelectronic element 638 may be part of a stackable package or a stackable microelectronic element that may be stacked into an assembly having two or more levels.

Although the present invention is not limited by any particular theory of operation, it is believed that providing one or more larger contact pads around all or a portion of the periphery of the microelectronic element will enhance the structural reliability of the assembly, particularly for drop testing and printed circuit board flex reliability. As is known to those skilled in the art, the location of the greatest stress on a microelectronic assembly is typically at the corner contact pads or at the contact pads located at the periphery of a microelectronic element. Thus, the present invention seeks to improve the structural reliability of the corner contact pads and/or the peripheral contact pads by providing larger contact pads at the corners and/or periphery. In other embodiments, larger contact pads are provided for high stress points of a microelectronic assembly and smaller contact pads are provided for lower stress points on the assembly. Using larger contact pads only where needed will enable the overall size of the microelectronic assembly to be reduced.

In one embodiment, the larger contact pads enable the volume of the conductive bonding material placed atop the larger contact pads to be greater than the amount placed atop the smaller contact pads. The increased volume of the conductive bonding material will enable the formation of a stronger bond with the electrical features engaging the contact pads. In embodiments using conductive pins or posts, the greater volume of conductive bonding material will enable the conductive bonding material to extend further up the outer surfaces of the conductive pins or posts for forming a stronger more reliable bond.

FIG. 10 shows a microelectronic assembly including a microelectronic element 738 having an array of contact pads 736 accessible at a first surface thereof. Each of the contact pads 736 has the same size. In the particular embodiment shown in FIG. 10, the microelectronic assembly is designed to have a pitch of about 0.8 mm or less so as to be reliable in a drop test. Although the point of highest stress occurs at the corner contact pads and the peripheral contact pads, all of the contact pads have the same size. In order to reduce the overall size of the array of contact pads, it may be desirable to use larger contact pads at high stress locations and smaller contacts pads at low stress locations.

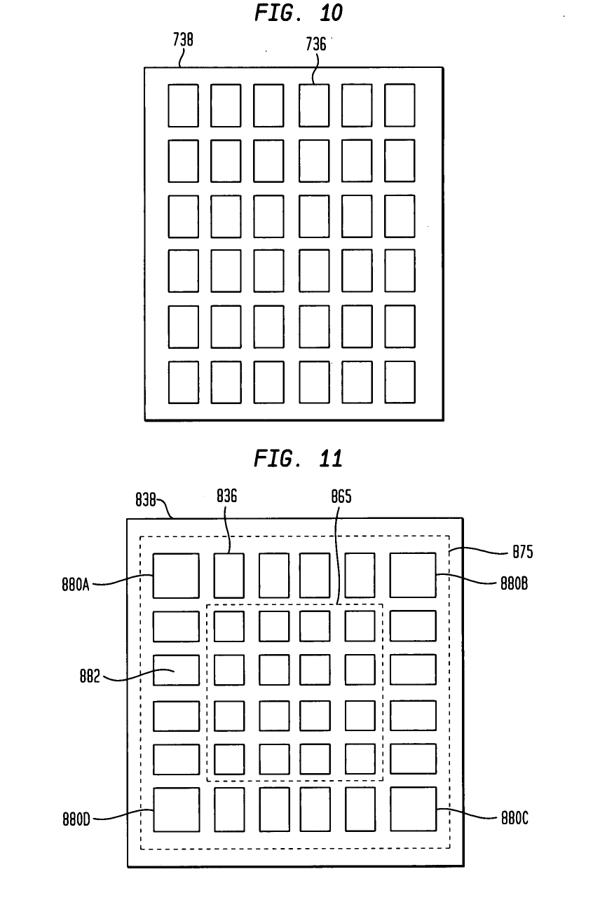

FIG. 11 shows one embodiment that provides for finer pitch at low stress locations, but which has peripheral contact pads of a larger size for performing reliably in a drop test. The microelectronic assembly includes a microelectronic element 838 having contact pads 836 accessible at a first surface thereof. The microelectronic element includes contact pads in a central region 865 and peripheral contact pads in a peripheral region 875. The contact pads in the central region 865 are smaller than the corner contact pads 880A-880D because less stress is registered in the central region. The microelectronic assembly 836 also includes rows of peripheral contacts 882 that extend between the corner contact pads 880A-880D. The rows of peripheral contacts 882 are larger than the contact pads in the central region but smaller than the corner contact pads 880A-880D.

The contact pads 736 on the microelectronic element 738 shown in FIG. 10 form a 6×6 array for a total of 36 contact pads. The microelectronic element 838 shown in FIG. 11 also has 36 contact pads. However, the size of the contact pad array found in the FIG. 11 embodiment is smaller than the size of the contact pad array found in the FIG. 10 embodiment. This is because the contact pads located in the central region 865 of the FIG. 11 embodiment are smaller than the contact pads located in the central region of the microelectronic element shown in FIG. 10. Only the corner contact pads 880A-880D in the FIG. 11 embodiment have the same size as the contact pads shown in the FIG. 10 embodiment. In addition, the rows of peripheral contacts in the embodiment of FIG. 11 are smaller than the rows of peripheral contacts in the FIG. 10 embodiment. As a result, the FIG. 11 embodiment is smaller in size, while providing the same number of inputs/outputs as is provided by the larger sized microelectronic element shown in FIG. 10.

Referring to FIG. 12, in one embodiment of the present invention, a microelectronic assembly includes a microelectronic element 938, such as a substrate or chip carrier, having an array of contact pads 936. The corner contact pads 980A-980D are larger than the remaining contact pads 936. The corner contact pads 980A-980D are made larger because stress analysis has shown that the points of greatest stress occur at the corner contacts. The larger corner contact pads enable more conductive bonding material to be placed atop the corner contact pads for forming a stronger bond with conductive elements, such as conductive posts, that are coupled with the corner contact pads. The larger corner contact pads may also accommodate larger diameter conductive posts for enhancing the strength of the bond between the posts and the contact pads.

In other embodiments, the conductive elements engaging the corner contact pads 980A-980D, such as conductive posts or pins, may have tips with a larger diameter. Such larger diameter tips will further enhance the structural reliability of an electrical interconnection formed between the conductive elements and the corner contact pads. Larger masses of conductive bonding material may also be used with such larger conductive posts.

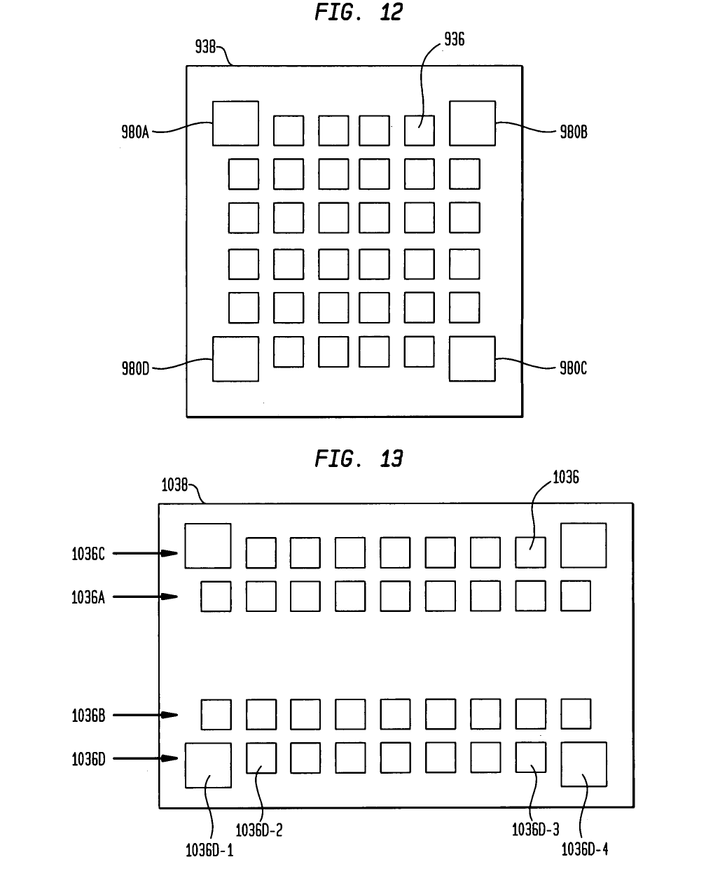

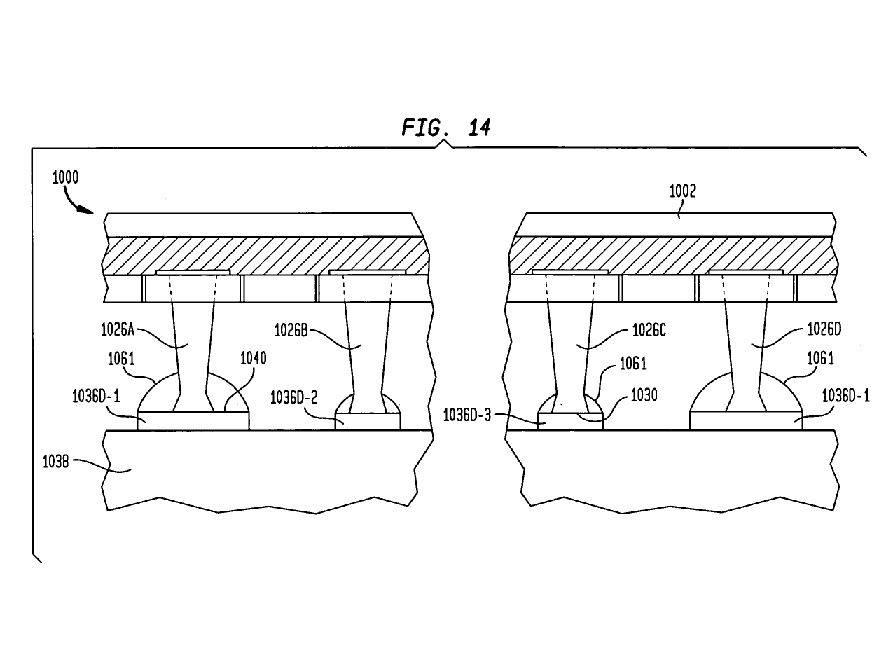

Referring to FIG. 13, in accordance with one preferred embodiment of the present invention, a microelectronic assembly includes a microelectronic element 1038 having rows of contact pads 1036. The inner rows of contact pads 1036A, 1036B have the same size. The outer rows of contact pads 1036C, 1036D have end contact pads that are larger than contact pads located between the end contact pads. For the reasons noted above, the larger end contact pads enhance the structural reliability of an electrical interconnection when electrical elements such as conductive posts or pins are coupled with the end contact pads. The larger end contact pads also enable increased volumes of conductive bonding material, such as solder, to be place atop the pads, which further enhances the reliability of the connection between the conductive posts and the contact pads.

FIG. 14 shows a microelectronic package being abutted against the contact pads on a simplified version of the microelectronic element 1038 shown in FIG. 13. The microelectronic element 1038 includes contact pads 1036D-1, 1036D-2, 1036D-3 and 1036D-4. The end contact pads 1036D-1 and 1036D-4 are larger than the two intermediate contact pads 1036D-2 and 1036D-3. In addition, conductive post 1026D that is coupled with end contact pad 1036D-4 is also larger in diameter than the conductive posts 1026B in contact with the smaller contact pads.

The microelectronic assembly 1000 includes a semiconductor chip package 1002 having conductive posts 1026A-1026D. Each of the conductive posts has a tip 1030 that is coupled with the top surface 1040 of the respective contact pads 1036D-1 through 1036D-4. A conductive bonding material 1061 such as solder is provided atop each of the contact pads 1036D-1 through 1036D-4. A larger volume of solder 1061 may be placed atop each of the end contact pads 1036D-1 and 1036D-4. The larger volume of the solder at the end contact pads enables the solder to extend further up the outer surface of conductive posts 1026A and 1026D. The increased surface area contact between the larger solder masses and the conductive posts 1026A, 1026D enhances the strength of the bond between end contact pads 1036D-1 and 1036D-4 and the respective conductive posts 1026A and 1026D, which enhances the structural reliability of the assembly.

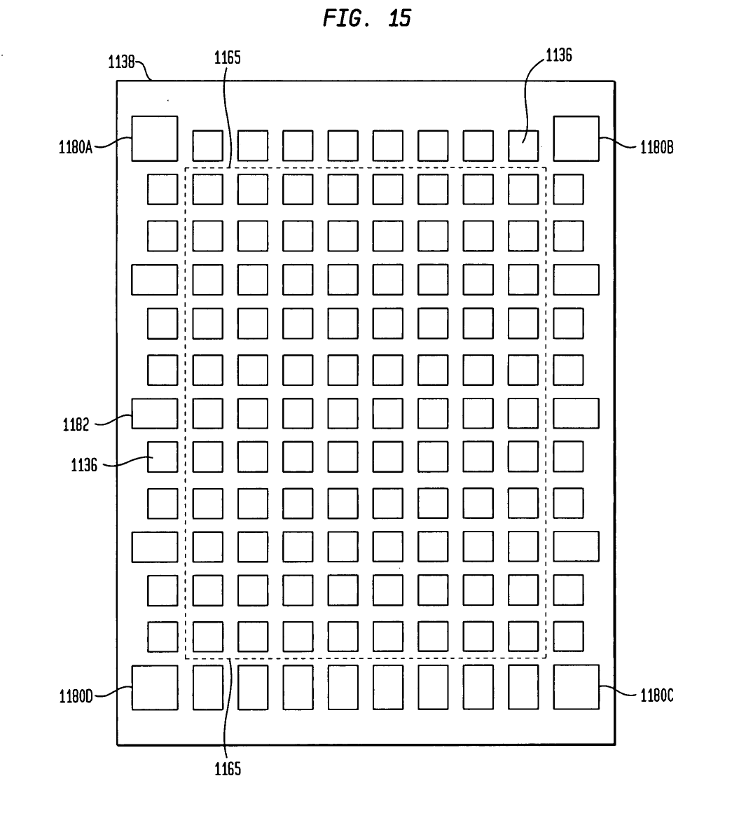

Referring to FIG. 15, in accordance with another preferred embodiment of the present invention, a microelectronic assembly includes a microelectronic element 1138 having contact pads 1136 accessible at a first surface thereof. The first surface of the microelectronic element 1138 includes a central region 1165 having contact pads 1136 that are smaller than at least some of the contacts pads 1180 located outside the central region 1165. The larger contact pads in the peripheral region of the microelectronic element 1138 include corner contact pads 1180A-1180D and intermediate peripheral contact pads 1182, at least some of which are larger than the contact pads in the central region 1165.

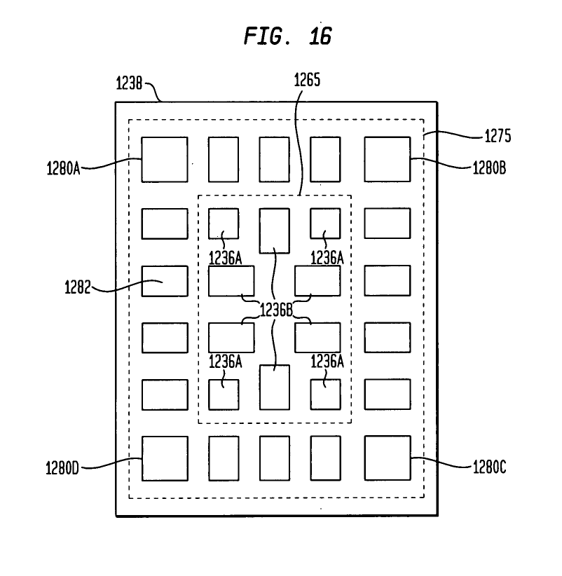

Referring to FIG. 16, in accordance with one embodiment of the present invention, a microelectronic assembly includes a microelectronic element 1238 having a central region 1265 and a peripheral region 1275 that surrounds the central region 1265. In the central region 1265, some of the contact pads 1236A are smaller than other contact pads 1236B. Thus, a first set of contact pads 1236A smaller than a second set of contact pads 1236B. The peripheral region 1275 of the microelectronic element 1238 includes peripheral contact pads. The peripheral contact pads include corner contact pads 1280A-1280D that are larger than the contact pads located in the central region 1265. As noted above, the larger area corner contact pads 1280A-1280D enable larger amounts of conductive bonding material such as solder to be placed atop the pads. Such conductive bonding material will form a more reliable electrical interconnection with conductive elements, such as conductive posts or pins, coupled with the corner contact pads 1280A-1280D. The peripheral region 1275 also includes intermediate peripheral contact pads 1282 that extend between the corner contact pads 1280A-1280D. The intermediate peripheral contact pads 1282 cover an area that is as large or larger than the second set of contact pads 1236B located in the central region 1265 of the microelectronic element 1238.

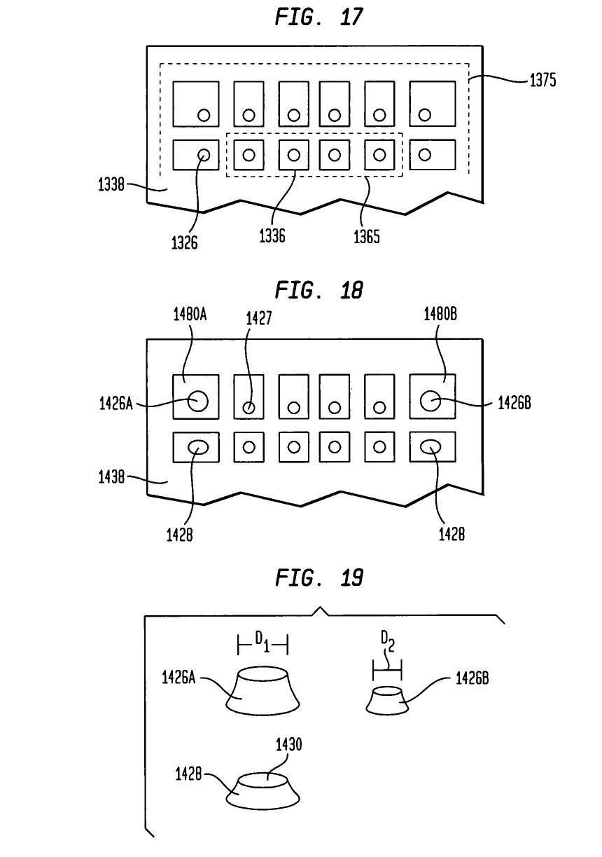

FIG. 17 shows a microelement 1338, in accordance another preferred embodiment of the present invention. The microelectronic element 1338 includes a central region 1365 having contact pads 1336 and a peripheral region 1375 outside the central region 1365. The peripheral region 1375 includes contact pads that are larger than the contact pads in the central region. Each of the contact pads has a conductive post 1326 electrically interconnected therewith. In FIG. 17, the conductive posts 1326 are shown in cross section at the tip end of the respective posts. A greater volume of conductive bonding material, such as solder, may be deposited atop the larger conductive pads in the peripheral region than the smaller sized conductive pads in the central region 1365. The greater volume of conductive bonding material preferably extends further up along the outer surfaces of the conductive posts for enhancing the structural stability of the connection between the conductive posts 1326 and the contacts pads.

FIG. 18 shows a microelectronic element 1438 that is similar to the microelectronic element shown in FIG. 17. In the FIG. 18 embodiment, the tips of the conductive posts 1426A, 1426B in contact with the larger corner contact pads 1480A, 1480B have a larger diameter than the tips of the conductive posts in contact with the intermediate contact pads between the corner contact pads 1480A, 1480B. The larger diameter conductive posts 1426A, 1426B form a stronger bond with the larger corner contact pads for enhancing the structural stability of the microelectronic assembly. In another embodiment, the tips of the conductive posts 1428 may be non-circular or elongated. The elongated tips of the conductive posts preferably enhance the surface area engagement between the conductive posts and the contact pads for improving the structural stability of the microelectronic assembly.

FIG. 19 shows a first conductive post 1426A having a larger diameter D₁ tip than the tip diameter D₂ of a second conductive post 1426B. FIG. 19 also shows a third conductive post 1428 having a tip 1430 that is non-circular or elongated.

An underfill material such as an epoxy or other polymeric material may be provided around the tips of the posts and around the contact pads, so as to reinforce the solder bonds. Desirably, this underfill material only partially fills the gap between the package and the circuit board. In this arrangement, the underfill does not bond the flexible substrate or the microelectronic device to the circuit board. The underfill only reinforces the posts at their joints with the contact pads. However, no reinforcement is required at the bases of the posts, inasmuch as the joint between the base of each post and the associated trace is extraordinarily resistant to fatigue failure.

The assembly is also compact. Some or all of the posts and contact pads are disposed in the area occupied by the microelectronic element, so that the area of circuit board occupied by the assembly may be equal to, or only slightly larger than, the area of the microelectronic element itself, i.e., the area of the front surface of the microelectronic element.

Numerous further variations and combinations of the features discussed above can be used. For example, where the contact pads are disposed in an array, such array need not be a rectilinear, regular array as described above. For example, contact pads may be disposed in an irregular pattern or in a circular, hexagonal or triangular array.

The foregoing discussion has referred to an individual microelectronic element. However, the package may include more than one microelectronic element or more than one substrate. Moreover, the process steps used to assemble the substrate, support elements and posts to chips may be performed while the chips are in the form of a wafer. A single large substrate may be assembled to an entire wafer, or to some portion of the wafer. The assembly may be severed so as to form individual units, each including one or more of the chips and the associated portion of the substrate. The testing operations discussed above may be performed prior to the severing step. The ability of the packages to compensate for non-planarity in a test board or in the wafer itself greatly facilitates testing of a large unit. In one embodiment, the posts may be fabricated separately from the substrate and traces and then assembled to the substrate.

In certain preferred embodiments of the present invention, a particle coating such as that disclosed in U.S. Pat. Nos. 4,804,132 and 5,083,697, the disclosures of which are incorporated by reference herein, may be provided on one or more electrically conductive parts of a microelectronic package for enhancing the formation of electrical interconnections between microelectronic elements and for facilitating testing of microelectronic packages. The particle coating is preferably provided over conductive parts such as conductive terminals or the tip ends of conductive posts. In one particularly preferred embodiment, the particle coating is a metalized diamond crystal coating that is selectively electroplated onto the conductive parts of a microelectronic element using standard photoresist techniques. In operation, a conductive part with the diamond crystal coating may be pressed onto an opposing contact pad for piercing the oxidation layer present at the outer surface of the contact pad. The diamond crystal coating facilitates the formation of reliable electrical interconnections through penetration of oxide layers, in addition to traditional wiping action.

As discussed above, the motion of the posts may include a tilting motion. This tilting motion causes the tip of each post to wipe across the contact pad as the tip is engaged with the contact pad. This promotes reliable electrical contact. As discussed in greater detail in the co-pending, commonly assigned application Ser. No. 10/985,126 filed Nov. 10, 2004, entitled “MICRO PIN GRID ARRAY WITH WIPING ACTION,” the disclosure of which is incorporated by reference herein, the posts may be provided with features which promote such wiping action and otherwise facilitate engagement of the posts and contacts. As disclosed in greater detail in the co-pending, commonly assigned application Ser. No. 10/985,119 filed Nov. 10, 2004, entitled “MICRO PIN GRID WITH PIN MOTION ISOLATION,” the disclosure of which is also incorporated by reference herein, the flexible substrate may be provided with features to enhance the ability of the posts to move independently of one another and which enhance the tilting and wiping action.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic assembly comprising:
a microelectronic package having a plurality of posts projecting from an exposed surface thereof; and
a microelectronic element having a first surface and an array of contact pads accessible at the first surface, wherein at least one of said contact pads is larger than another one of said contact pads.

2. The assembly as claimed in claim 1, wherein said array of contact pads includes a central region and a peripheral region, and wherein at least one of said contact pads in said peripheral region is larger than at least one of said contact pads in said central region.

3. The assembly as claimed in claim 2, wherein said array of contact pads has a rectangular shape, and wherein corner contact pads in said rectangular shaped array are larger than said contact pads in said central region.

4. The assembly as claimed in claim 1, wherein said at least one larger contact pad covers a larger area of the first surface of said microelectronic element than said at least one contact pad in the central region.

5. The assembly as claimed in claim 1, wherein at least some of said posts are conductive posts for electrically interconnecting said microelectronic package and said microelectronic element.

6. The assembly as claimed in claim 1, wherein at least some of said posts are non-conductive for mechanically interconnecting said microelectronic package and said microelectronic element.

7. The assembly as claimed in claim 5, wherein at least some of said conductive posts are electrically interconnected with at least some of said contact pads.

8. The assembly as claimed in claim 5, wherein said conductive posts have tips remote from said microelectronic package.

9. The assembly as claimed in claim 8, wherein said tips confront said contact pads for electrically interconnecting said conductive posts with said contact pads.

10. The assembly as claimed in claim 8, wherein at least some of said conductive post tips have larger cross-sectional diameters than other ones of said conductive post tips.

11. The assembly as claimed in claim 10, wherein said conductive post tips having larger cross-sectional diameters are aligned with said larger contact pads in the peripheral region of said array of contact pads.

12. The assembly as claimed in claim 8, wherein said tips of at least some of said conductive posts have cross sections that are non-circular.

13. The assembly as claimed in claim 12, wherein said conductive post tips having non-circular cross sections are aligned with said larger contact pads in the peripheral region of said array of contact pads.

14. The assembly as claimed in claim 1, wherein said microelectronic package comprises a semiconductor chip.

15. The assembly as claimed in claim 1, wherein said microelectronic package comprises a semiconductor wafer.

16. The assembly as claimed in claim 1, wherein said microelectronic element comprises a circuitized substrate.

17. The assembly as claimed in claim 16, further comprising conductive traces provided on said circuitized substrate.

18. The assembly as claimed in claim 16, wherein said circuitized substrate comprises a printed circuit board.

19. The assembly as claimed in claim 16, wherein said circuitized substrate comprises a dielectric sheet.

20. The assembly as claimed in claim 1, wherein said microelectronic element comprises a second microelectronic package that is stackable with said first microelectronic package.

21. The assembly as claimed in claim 1, further comprising masses of electrically conductive bonding material for interconnecting said posts and said contact pads.

22. The assembly as claimed in claim 21, wherein said masses of electrically conductive bonding material form fillets extending around tips of said posts.

23. The assembly as claimed in claim 21, wherein said electrically conductive bonding material comprises solder.

24. The assembly as claimed in claim 21, wherein said masses of an electrically conductive bonding material covering said larger contact pads have a greater volume than said masses of an electrically conducting bonding material covering said at least one smaller contact pad.

25. The assembly as claimed in claim 1, further comprising a compliant material disposed between said microelectronic package and said microelectronic element.

26. A microelectronic assembly comprising:
a first microelectronic element having a plurality of posts projecting from an exposed surface thereof, wherein said posts have tips remote from said exposed surface;
a second microelectronic element having a first surface and an array of contact pads accessible at the first surface, said array of contact pads including a peripheral region and a central region, wherein at least some of said contact pads in the peripheral region are larger than at least some of said contact pads in the central region.

27. The assembly as claimed in claim 26, wherein said posts on said first microelectronic element are conductive posts.

28. The assembly as claimed in claim 26, wherein said larger contact pads in said peripheral region cover a larger area than said smaller contact pads in said central region.

29. The assembly as claimed in claim 26, wherein said first microelectronic element comprises a semiconductor package.

30. The assembly as claimed in claim 29, wherein said second microelectronic element is selected from the group consisting of a second microelectronic package, a circuitized substrate, a printed circuit board and a dielectric sheet.

31. The assembly as claimed in claim 26, wherein said second microelectronic element comprises posts projecting from an exposed surface thereof.

32. The assembly as claimed in claim 31, wherein said posts projecting from the exposed surface of said second microelectronic element comprise conductive posts.

33. The assembly as claimed in claim 26, wherein said conductive posts have tips remote from said exposed surface.

34. The assembly as claimed in claim 33, wherein at least some of said conductive post tips have larger diameters than other ones of said conductive post tips.

35. The assembly as claimed in claim 34, wherein said larger conductive posts are aligned with said larger contact pads.

36. The assembly as claimed in claim 33, wherein at least some of said conductive post tips have cross sections that are non-circular.

37. A microelectronic assembly comprising:
a microelectronic package having a plurality of posts projecting from an exposed surface thereof;
a microelectronic substrate having a first surface with a plurality of contact pads accessible at the first surface;
said contact pads forming an array of contact pads having a central region and a peripheral region, wherein at least some of said contact pads in the peripheral region cover a larger area of said microelectronic substrate than at least some of said contact pads in the central region.

38. The assembly as claimed in claim 37, wherein said posts are conductive posts for electrically interconnecting said microelectronic package and said microelectronic substrate.

39. The assembly as claimed in claim 38, wherein said conductive posts have tips remote from said exposed surface, and wherein said conductive post tips in contact with said larger contact pads in the peripheral region have a larger diameter than said conductive post tips in contact with said smaller contact pads.

40. The assembly as claimed in claim 38, further comprising a mass of a fusible material interconnecting each of said conductive posts with one of said contact pads.

41. The assembly as claimed in claim 40, wherein said masses of a fusible material interconnecting said conductive posts with said larger contact pads have a greater volume than said masses of a fusible material interconnecting said conductive posts with said at least some of said contact pads in the central region.

42. The assembly as claimed in claim 37, wherein said array of contact pads comprises rows of contact pads and wherein at least some of said contact pads in outer ones of said rows cover larger surface areas than at least some of said contact pads in inner ones of said rows.

43. The assembly as claimed in claim 37, wherein the array of contact pads comprises corner contact pads and wherein said corner contact pads are larger in area than said contact pads in the central region.

44. A microelectronic assembly comprising:
a microelectronic package having a plurality of conductive posts projecting from an exposed surface thereof, said conductive posts having tips remote from said exposed surface, wherein at least one of said conductive post tips has a larger diameter than other ones of said conductive post tips; and
a circuitized substrate having an array of contact pads accessible at a first surface thereof, said array of contact pads including a central region and a peripheral region, wherein said array of contact pads includes at least one large area contact pad in the peripheral region and at least one small area contact pad, wherein said at least one of said conductive post tips having a larger diameter is electrically interconnected with said at least one large area contact pad.

45. The assembly as claimed in claim 44, further comprising masses of conductive bonding material provided atop said contact pads for electrically interconnecting said conductive posts with said contact pads.

46. The assembly as claimed in claim 45, wherein the volume of said mass of conductive bonding material atop the at least one large area contact pad is greater than the volume of said mass of conductive bonding material atop the at least one small area contact pad.

47. A method of making a microelectronic assembly comprising:
providing a microelectronic element having a first surface and an array of contact pads accessible at the first surface, said array of contact pads including a central region having one or more smaller contact pads and a peripheral region having one or more larger contact pads;
providing a microelectronic package having a plurality of conductive posts projecting from an exposed surface thereof, said conductive posts having tips remote from the exposed surface;
depositing a mass of a conductive bonding material atop each of said contact pads;
abutting the tips of said conductive posts against said masses of a conductive bonding material for electrically interconnecting said microelectronic element and said microelectronic package.
